(19) United States
(12) Patent Application Publication
(10) Pub. No.: US 2008/0150085 A1
(43) Pub. Date: Jun. 26, 2008

(54) GRUPPE-III-NITRID-HALBLEITERBAUELEMENT MIT HOCH P-LEITFAHIGER SCHICHT

(76) Inventors: Armin Dadgar, Berlin (DE); Alois Krost, Berlin (DE)

Correspondence Address: WARE FRESSOLA VAN DER SLUYS & ADOLPHSON, LLP, BRADFORD GREEN, BUILDING 5, 755 MAIN STREET, P O BOX 224, MONROE, CT, 06468, US

(21) Appl. No.: 11/959,626

(22) Filed: Dec. 19, 2007

Related U.S. Application Data
(60) Provisional application No. 60/876,907, filed on Dec. 22, 2006.

(51) Int. Cl. H01L 29/20; H01L 21/205

(52) U.S. Cl. 257/615; 438/494; 257/E29.089; 257/E21.108

(57) ABSTRACT

Group III nitride layers which are grown with standard c-axis orientation have a maximum hole concentration by means of magnesium doping of around 5×10¹⁷ cm⁻³. This restriction of the doping results in a limitation of the possible component power. The object is to achieve a higher hole concentration and thus conductivity of the p-doped layer. This is made possible by the growth of higher index facets, which proceeds by roughening of the c-planar surface, structuring and subsequent preferentially lateral overgrowth with magnesium-doped group III nitride layers. Hole concentrations of over 5×10¹⁷ cm⁻³ on c-axis oriented GaN are possible

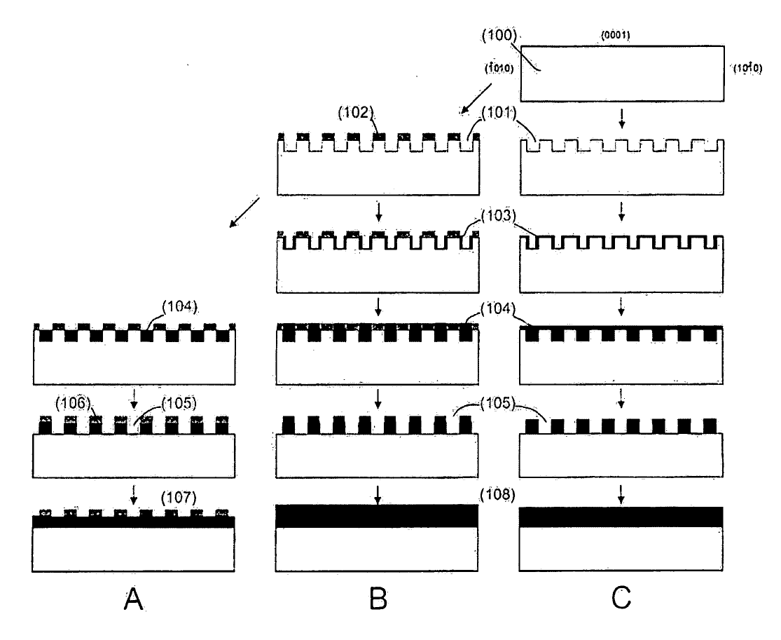

Group III nitride semiconductor components have acquired considerable significance with regard to light-emitting diodes in the field of optoelectronics and now also with regard to lasers in the UV/blue range. In the electronics sector, this material is of interest above all for transistors as well as other components such as high voltage components.

Group III nitrides preferably grow in so-called c-axis orientation generally with cation termination. Other growth directions are less preferred by most growth processes or lead to lower quality layers. High dopant concentrations of the magnesium usual for p-type doping lead, from a chemical concentration of around 5×10¹⁹ cm⁻³, to the formation of precipitates in the form of Mg-rich clusters, which result in local changes in polarity and in compensation of the p-type conductivity. Such precipitates act as troublesome deep centers and reduce hole concentration.

At present, many components which contain a p-type conductive layer are limited by the high acceptor binding energy and the described limited solubility of the p-dopants, which leads as a rule to a maximum charge carrier concentration of below 5×10¹⁷ cm⁻³. Associated with this are low conductivity and poor current spreading, which may in turn lead to high ohmic losses and low component performance.

The technical problem underlying the invention is that of bringing about higher p-type conductivity on c-planar group III nitride layers than with known semiconductor components.

The invention is described below firstly with regard to its method aspect, which is intended to make it easier to understand the device aspect of the invention described thereafter.

According to a first aspect of the invention, a method is indicated for producing a group III nitride semiconductor component. The method has the steps of:
producing at least one first c-axis oriented group III nitride layer portion on a substrate layer, which portion extends less far laterally than the substrate layer and which has an interface of the index {h,k,−(h+k),l}, h, k, and l being integers and at least one of the indices h and k being an integer greater than or equal to 1; and
depositing at least one second c-axis oriented and p-conductive group III nitride layer portion with a hole concentration of over 5×10¹⁷ cm⁻³ on the interface of the index {h,k,−(h+k),l} of the first c-axis oriented group III nitride layer portion in a growth direction perpendicular to the interface.

In the method according to the invention, in a first step a substrate with at least one first c-axis oriented group III nitride layer portion is produced. This group III nitride layer portion has an interface of the index {h,k,−(h+k),l. The indices h, k and l are integers, at least one of the indices h and k being an integer greater than or equal to 1. A face or group of faces which fulfils this condition is also described for the purpose of this application as being of a “higher index”.

A c-axis oriented group III nitride layer portion or a c-axis oriented layer should be understood to be a layer portion or a layer which comprises a {0001} surface which is perpendicular to a depth direction of the substrate. In the case of a disc- or plate-shaped substrate, the depth direction runs from the substrate top towards the substrate bottom. Such layers are also known as c-planar.

In the method according to the invention, upon production of the at least one first c-axis oriented group III nitride layer portion on a substrate layer a c-axis oriented group III nitride layer portion is thus created on the one hand, which on the other hand, however, has a higher index interface, to be understood here as a temporary outer face, i.e. an interface with the air. This is provided, in the further procedure, for the deposition of at least one second c-axis oriented group III nitride layer portion.

It has been found that the incorporation of p-dopants, for example magnesium incorporation, into group III nitrides on facets of lower polarity allows a higher hole concentration or is even possible in a higher chemical concentration before precipitation occurs. This is particularly successful on the a- and m-faces, but also, albeit not quite so efficiently, on faces such as the {10 1̅2} or {11 2̅2} faces. In general, greater magnesium incorporation is observed on lower polarity faces than on the Ga- or N-terminated c-planar (0001) or (000 1̅) face. The reason for this is probably the strong tendency of the magnesium to float on the surface during layer growth on these faces and the incorporation of compensating Mg clusters then arising when sufficient Mg is accumulated. Due to the different binding conditions, or the generally simultaneously occurring surface atoms of Ga and N, lower polarity surfaces offer stabler incorporation conditions for the dopants, which reduce this accumulation.

The method according to the invention uses these effects to produce a highly doped p-conductive and simultaneously c-axis oriented group III nitride layer. This thus makes possible on the one hand the advantageous use of the c-plane for further layer deposition on the group III nitride layer when producing a component and on the other hand a high hole concentration not hitherto achieved for a functional group III nitride layer of this orientation.

A hole concentration of over 5×10¹⁷ cm⁻³ at room temperature is achieved by incorporation of a dopant, for example magnesium, in a correspondingly high concentration. The stated threshold value for the hole concentration relates to values which may be determined by means of known measuring methods, such as Hall effect measurements and C-V measurements at room temperature. The dopant concentration of the p-type dopant is generally higher than the hole concentration achieved because of compensation effects. Room temperature is understood to mean 20 degrees Celsius.

In the present description round brackets ( ) are used to indicate a crystal face, i.e. for example (0001) or (000 1̅) etc. In addition, the common letter abbreviations are also used, i.e. for example c-plane, m-plane etc. Curly brackets { } or { } indicate a group of equivalent faces, for example {0001} stands for the group of the two planes (0001) and (000 1̅) or {11 2̅0} stands for the group of planes (11 2̅0), ( 1̅1̅20), ( 2̅110), (2 1̅1̅0), (1 2̅10) and ( 1̅2 1̅0).

Exemplary embodiments of the method according to the invention are described below. The exemplary embodiments may be combined together.

In a first exemplary embodiment, production of the substrate comprises a step of depositing a c-axis oriented group III nitride layer and a step of producing trenches in the c-axis oriented group III nitride layer using a lithographic method. The trenches may be arranged parallel to one another. In an alternative exemplary embodiment the trenches intersect with one another. It is advantageous in this case for the trenches to intersect with one another at an angle of 120°. In this way, columnar structures arise between the trenches.

In a further exemplary embodiment, production of the substrate comprises a step of producing ridges using a lithographic method, the ridges comprising side walls of the index {h,k,−(h+k),l}. The ridges have side walls of the index {h,k,−(h+k),l}. In this exemplary embodiment, deposition of the second group III nitride layer portion comprises selective epitaxial deposition of the p-conductive region between the ridge structures, and not on a c-face of the ridge structures. Selective epitaxial deposition may be achieved in a manner known per se by producing suitable growth conditions. An alternative possibility for selective epitaxial deposition of the p-conductive region between the ridge structures is to mask the c-face of the ridge structures. Examples of suitable materials for covering the c-face are SiO₂, SiN, or other per se known mask materials.

In a further exemplary embodiment, production of the substrate comprises a step of roughening a substrate surface layer by wet or dry chemical etching. In this embodiment, group III nitride layer portions with a higher index interface arise on a microscopic scale on a c-axis oriented group III nitride substrate layer. The term interface should here again be understood to mean a temporary outer face, i.e. an interface for example with the air. After deposition, this outer surface forms an interface with the second group III nitride portion deposited thereon.

In a further exemplary embodiment, production of the substrate comprises a step of depositing a c-axis oriented group III nitride layer and creating interfaces of the index {h,k,−(h+k),l} on the c-axis oriented group III nitride layer during growth thereof, h, k, and l being integers and at least one of the indices h and k being an integer greater than or equal to 1, and deposition of the second group III nitride layer portions taking place with the assistance of epitaxial overgrowth of the interfaces created.

In a further exemplary embodiment, interfaces of the index {h,k,−(h+k),l} are produced by deposition of layers acting as antisurfactants, h, k, and l being integers and at least one of the indices h and k being an integer greater than or equal to 1.

In another exemplary embodiment, interfaces of the index {h,k,−(h+k),l} are produced by producing highly strained layers with a lattice mismatch of >1%, h, k, and l being integers and at least one of the indices h and k being an integer greater than or equal to 1. In a further exemplary embodiment, interfaces of the index {h,k,−(h+k),l} are produced by means of a V/III precursor ratio of less than 1000 during layer deposition of a Ga-rich group III nitride layer and/or growth rates of above 5 μm/h, h, k, and l being integers and at least one of the indices h and k being an integer greater than or equal to 1.

In one exemplary embodiment, production of the substrate includes a step of providing a substrate with a c-axis oriented group III nitride layer and a step of structuring a c-face of the substrate to expose an m-face. Furthermore, the step of depositing the second group III nitride layer portion includes a step of preferentially lateral growth of the second group III nitride layer portion on the m-face.

In a further exemplary embodiment, production of the substrate includes a step of etching trenches and a subsequent step of filling the trenches with the second group III nitride layer portion, regions of the trenches located next to an upper trench edge being provided with a growth-inhibiting mask.

In this exemplary embodiment too, provision may be made in a variant for the trenches to be produced in an intersecting arrangement, an angle of 120° again being preferred.

In a further exemplary embodiment, the step of producing the substrate comprises the following steps:
providing a substrate with a group III nitride layer;
a first step of etching first trenches and a subsequent first step of filling the trenches, followed by
a second step of etching complementarily staggered second trenches and a second step of filling the complementarily staggered second trenches.

The above-stated methods, which may also be used in combination, serve to achieve high hole concentrations in a c-axis oriented group III nitride layer. It goes without saying that the stated methods may also be applied to different group III nitride layers of a complex multilayer structure, as present for example in a semiconductor laser or a hetero bipolar transistor.

For laser structures and in particular p-conductive HBT base layers, thin highly p-conductive layers are also necessary. Such a thin highly p-conductive layer may for example be produced by firstly producing a thick layer and then etching this back.

The group III nitrides are formed by one or more elements of group III of the periodic system of elements, in particular Al, Ga, In, and by nitrogen. Examples are the binary compounds GaN, AlN, InN, the ternary compounds of the type AlGaN, InGaN, or AlInN and the quaternary compounds of the type AlGaInN. In the case of the ternary and quaternary compounds, different stoichiometries are known with regard to the relative proportions of the group III metals.

A second aspect of the invention takes the form of a semiconductor component with a c-axis oriented group III nitride layer, which is composed of a plurality of c-axis oriented group III nitride layer portions. These group III nitride layer portions adjoin one another and thus in this way together form the group III nitride layer. At least a first one of these group III nitride layer portions shares an interface of the index {h,k,−(h+k),l} with at least one second p-conductive group III nitride layer portion of the group III nitride layer produced temporally separately from the first group III nitride layer portion. H, k and l are here integers, and at least one of the two indices h and k is an integer greater than or equal to 1. In the semiconductor component according to the invention, the second group III nitride layer portion has a hole concentration of over 5×10¹⁷ cm⁻³ at room temperature.

The semiconductor component according to the invention thus has a high p-type conductivity with a hole concentration of over 5×10¹⁷ cm⁻³ in the group III nitride layer, although the group III nitride layer is c-axis oriented. Such a high p-type conductivity may be achieved in the case of already known components only in an a- or m-axis oriented group III nitride layer, but not in a c-axis oriented group III nitride layer.

In the case of the semiconductor component of the second aspect of the present invention, p-doping of the group III nitride layer does not take place or takes place only to a small extent via incorporation in the c-plane, but instead above all via incorporation in higher index crystal facets. Thus, very high hole concentrations of over 5×10¹⁷ cm⁻³ may be achieved, such as are very useful for example in injection lasers and also in LEDs. Furthermore, hole concentrations may be achieved which are of a level essential for hetero bipolar transistors (HBTs) but which may also be used in high voltage components.

The structure of the semiconductor component of the second aspect of the invention is related to the procedure according to the first aspect of the invention. The group III nitride layer of the semiconductor component according to the invention comprises microscopically detectable structuring in group III nitride layer portions which in certain exemplary embodiments form in particular lateral structuring of the group III nitride layer. Typically, these group III nitride layer portions extend by an amount ranging from a few nanometers, typically 100 nm, into the micrometer range between two interfaces of the same indices. This structuring reflects the procedure according to the invention.

The group III nitride layer is thus composed of group III nitride layer portions, from which first and second layer portions differ in that they were produced temporally separately. This means that one of these two group III nitride layer portions was produced before the other. Of course, the group III nitride layer may contain a large number of pairs of adjoining first and second group III nitride layer portions, in particular it may be composed wholly of first and second group III nitride layer portions.

This feature of producing the first and second group III nitride layer portions temporally separately, which in itself relates to a procedure and in particular to the procedure according to the invention, is reflected detectably in the structure of the semiconductor element, since a first and a second group III nitride layer portion in each case share an interface of the index {h,k,−(h+k),l}, h, k, and l being integers and at least one of the indices h and k being an integer greater than or equal to 1. Interfaces having this feature are also described herein as higher index interfaces. This interface is located between the first and the second group III nitride layer portion.

Such an interface, which points unambiguously to temporally separate production of the adjoining first and second group III nitride layer portions, may be detected in a cross-sectional transmission electron micrograph. Alternatively or in addition, such an interface may be detected with a scanning electron microscope, preferably a high-resolution field emission scanning electron microscope (FE-SEM). An FE-SEM is capable of detecting slight growth defects at the interface which are indicative of the temporally separate deposition of the first and second group III nitride layer portions.

At the interface between the two group III nitride layer portions small defects inevitably arise, which typically display regularity. To detect the structure according to the invention, it is also possible, depending on the size of the structure, to use micro-photoluminescence or cathodo luminescence, in plan view or in cross-section.

In exemplary embodiments in which there is a major difference in concentration of holes between the first and second group III nitride layers, this major contrast between the first and second group III nitride layer portions may likewise be detected by means of an FE-SEM. Because of their optionally different hole concentrations and depending on growth development, the first and second group III nitride layer portions also have characteristic light emission features when excited appropriately by suitable light or by electrons.

As is revealed by the above description of preferred exemplary embodiments, in the semiconductor component according to the invention the group III nitride layer may have a hole concentration of over 5×10¹⁷ cm⁻³ in both the first and the second group III nitride layer portion. This is achieved as described above for example by producing the group III nitride layer portions in different masking steps, the masks of the different masking steps being arranged in staggered manner, such that overall a continuous, highly p-conductive and c-axis oriented group III nitride layer is obtained.

The hole concentration in the second group III nitride layer portion may be detected by means of local measurement methods such as scanning capacitance microscopy (SCM). In this measurement method a capacitance-voltage measurement (C-V measurement) is performed with a conductive tip of an atomic force microscope (AFM). With this method, in the group III nitride layer spatial structures which have dimensions of under 1 μm may be resolved with regard to their p-conductivity.

In exemplary embodiments in which, in the first and second group III nitride layer portions, a group III nitride layer of constantly high p-conductivity in the lateral direction is present overall, the hole concentration may also be determined using the Hall effect if no further readily conductive layer is arranged under the group III nitride layer.

Exemplary embodiments of the semiconductor component according to the invention are described below.

In one exemplary embodiment, the first and the second group III nitride layer portions are cation-terminated.

In a further exemplary embodiment, the first and second group III nitride layer portions form a structure of ridges and trench fillings grown laterally between the ridges, the trench fillings and ridges having mutually adjoining side walls which in each case form the interface of index {h,k,−(h+k),l}, i.e. the higher index interface.

In a further exemplary embodiment, the first group III nitride layer portions additionally display a hole concentration of over 5×10¹⁷ cm⁻³. With this exemplary embodiment, it is possible to produce a continuously highly p-conductive c-axis oriented group III nitride layer, which is composed of the first and second group III nitride layer portions, which are arranged alternately in the lateral direction.

In another exemplary embodiment, the higher index interface is an a-face or an m-face of the first or second group III nitride layer portion. Here the group III nitride layer is structured into lateral group III nitride layer portions, which share an interface oriented perpendicularly to the c-plane. The a- or m-planes with the index {11 2̅0} for the a-planes and {10 1̅0} for the m-planes are thus positioned perpendicularly to the c-plane, which constitutes the otherwise usual growth surface for group III nitrides.

This cannot happen in a normal growth mode in standard epitaxy for group III nitride. Suitable therefor, for example, are the methods already described in greater detail above
roughening of the surface by means of in or ex situ masking
etching of structures which are mainly laterally overgrown
creation of three-dimensional structures by selective epitaxy and lateral overgrowth of the structures with a magnesium-doped group III nitride layer.

Local p-type doping may take place, for instance, after a one-off etching step followed by preferably lateral overgrowth, but also continuous layers through repeated etching after first overgrowth and subsequent further overgrowth, such that a continuously p-conductive layer is achieved by the staggered etching.

Alternatively, surfaces of lower polarity may be created by modifying the growth conditions to the effect that the surface is roughened. This is achieved by means of very high Si concentrations, which only makes sense in connection with an abrupt p/n junction, in situ or ex situ nano masks consisting of an antisurfactant such as silicon nitride or silicon oxide and subsequent three-dimensional growth or growth at low temperatures, V/III ratios or extremely high growth rates, which likewise leads to three-dimensional growth. In addition, highly strained layers may cause such three-dimensional growth, but the possible use of such layers is dependent on the component type.

Further exemplary embodiments are described with reference to the FIGURE.

The FIGURE is divided from left to right into three portions A, B and C, which show different variants of the procedure according to the invention. Common to all three procedures A, B and C is the starting structure used, i.e. a c-axis oriented substrate 100 with a (0001) substrate surface and for example a ( 1̅010) and a (10 1̅0) side face, which is provided at the start of the method. To simplify the graphic representation, this is only shown in portion C of the FIGURE. Arrows indicate the path taken by the further procedures A, B and C branching out therefrom.

The generation of local highly p-type doped group III nitride layer portions, as are necessary for example in components such as those shown in US2004173801 and DE10259373, may be achieved by various variant methods, starting with substrate 100. The variant methods A, B and C illustrated here include structuring of the (0001) surface with trenches or holes 101 and subsequent lateral overgrowth of these trenches or holes.

In all the variants, the substrate 100 is structured by etching trenches or holes 101. It is preferable if, when etching the structures, lateral m-plane surfaces are created, i.e. when etching holes hexagonal geometries with m-plane facets are preferable. However, a-plane side faces of the index { 1̅1-20} or other higher index facets may be produced.

The remaining ridge structures which have not been removed form first group III nitride layer portions with a (0001) surface and m-plane side faces. Then overgrowth proceeds in the trenches or holes 101 either selectively using a mask 102 on the unetched regions (variants A and B) or non-selectively without using a mask (variant C). These second group III nitride layer portions 103 are deposited on the m-plane ( 1̅010) and (10 1̅0) side faces of the ridge structures between the trenches or holes 101. Mg-doping is performed during growth of the second group III nitride layer portions. Doping during growth of the second group III nitride layer portions 103 is preferable to implantation, since after implantation unhealable compensating damage always remains, which partially compensates doping; for the purposes of the present invention, however, it is intended to achieve high p-type conductivity.

Deposition of the second group III nitride layer portions 103 proceeds until the trenches 101 have preferably been completely filled, resulting in a group III nitride layer 104. In variant A growth proceeds to the upper edge of the ridges. In variant B growth of the layer 104 proceeds as far as the upper edge of the mask 102, and in variant C growth of the layer 104 proceeds until planarization is achieved. With regard to variant C it should be noted that growth on the c-face leads to a lower hole concentration and should therefore be avoided, for example by stopping growth prior to significant vertical growth.

The resultant group III nitride layer thus contains first group III nitride layer portions, which are part of the originally provided substrate 100, and second group III nitride layer portions 104, which have been deposited after structuring of the substrate. The first and second group III nitride layer portions are both c-axis oriented and in each case share an m-plane interface, or in other exemplary embodiments an a-plane interface of the index { 1̅010} or {10 1̅0}. At this stage in the method, only the second layer portions 104 are highly p-conductive, with a hole concentration of over 5×10¹⁷ cm⁻³.

Through optional further etching of trenches 105, preferably in the lateral direction slightly into the just grown second group III nitride layer portions, so as to avoid a residual n-type region, and through repeated lateral overgrowth—possibly with renewed masking 106 as shown in example A—highly conductive p-type regions 108 may also be achieved without any vertically grown portion 107 and thus with continuously high conductivity.

In one exemplary embodiment, lateral growth preferably proceeds on the m-face and for example in metal organic vapor phase epitaxy (MOVPE) in that the V/III ratio, the temperature and/or the reactor pressure are kept relatively high, which, apart from in the case of the temperature, is also beneficial to the incorporation of Mg.

The structures to be overgrown are ideally masked for the above-mentioned components on the upper planar c-face of the GaN. Of the common mask materials, the mask material SiN is here preferable to SiO₂, since it is markedly more stable during growth and is stabilized by the nitrogen precursor pressure present.

It is best to avoid the incorporation of Si or oxygen, which would compensate the effect of p-type doping through the incorporation of n-type dopants. This is known per se.

Complete planarization of the surface is possible through a suitable choice of the nitrogen particle pressures, such that no or only minimal exaggerated growth occurs at the mask edge. If this does occur and is unwanted, it may be removed, for example, by sputtering from the side. Without a mask, removal of the upper, less conductive p-type layer, for example by dry etching, is necessary as a rule for the above-stated component structures.

If Schottky contacts are applied, healing of the etching damage at high temperatures of between 700-1200° C. as far as possible with ammonia flow is generally indicated.

As an alternative to etching of the structures, a masking layer may also assist in the selective epitaxy of n-type material. The ridge structures constructed in this way, ideally with vertical side walls, are filled laterally with the magnesium-doped layer in a lateral growth mode, optimally after removal of the masking layer. This approach is of particular interest for structures mentioned in US 2004/173801 or DE 102 59 373.

Production of rough surfaces may proceed, aside from through suitable growth parameters, for example also through an SiN mask deposited in situ. To this end, growth is stopped before or on a p-type outer layer by switching off gas inflow and a masking layer is grown of the order of a small number of monolayers by simultaneous feed of ammonia and silicon. This layer inhibits growth aside from in a few locations which remain bare and where, with further growth, small, generally pyramidal islands grow. These have facets of lower polarity, which, as a result of suitable growth conditions, may also be perpendicular, i.e. take the form of a- or m-faces. Such suitable growth conditions have already been mentioned above. After growth of a sufficiently thick layer, the latter is completely planar. The main disadvantage here is that an increasing proportion of the growth proceeds on the c-face, whereby the charge carrier concentration decreases towards the top.

Possible component applications range from simple light emitters such as LEDs through lasers to high frequency and high voltage components such as HBTs and high voltage switches. In the case of HBTs, a high hole concentration of the base layer is a prerequisite for high component efficiency. After growth of a base layer in accordance with one of the methods stated here, the component or the layer sequence hitherto existing has in turn to be overgrown, which ideally proceeds without further interruption in growth, i.e. any masking remaining as in example A has to be removed and thus growth interrupted. However, if the growth conditions as claimed in claim 6 are selected, the masking may be dispensed with, since then almost no vertical growth takes place.

The examples stated herein are possible, after adaptation to the respective particular features of the methods, with all epitaxial growth methods such as for example hydride vapor phase epitaxy (HVPE), molecular beam epitaxy (MBE) and all precursors which may be used for group III and group V elements.

### REFERENCES

[Figge] Stephan Figge, Roland Kroger, Tim Böttcher, Peter L. Ryder, and Detlef Hommel, Appl. Phys. Lett. 81, 4748 (2002)
[Kaeding] J. F. Kaeding, H. Asamizu, H. Sato, M. Iza, T. E. Mates, S. P. DenBaars, J. S. Speck, and S. Nakamura, Appl. Phys. Lett. 89, 202104 (2006)
[McLaurin] M. McLaurin, T. E. Mates, F. Wu, and J. S. Speck, J. Appl. Phys. 100, 063707 (2006)

1. A semiconductor component with a c-axis oriented group III nitride layer, which is composed of a plurality of c-axis oriented group III nitride layer portions, which adjoin one another and of which at least one first group III nitride layer portion shares an interface of the index {h,k,−(h+k),l} with at least one second, p-conductive group III nitride layer portion of the group III nitride layer produced temporally separately from the first group III nitride layer portion, which second, p-conductive group III nitride layer portion has a hole concentration of over 5×10¹⁷ cm⁻³ at room temperature, h, k and l being integers and at least one of the indices h and k being an integer greater than or equal to 1.

2. The semiconductor component as claimed in claim 1, in which the first and second group III nitride layer portions are cation-terminated.

3. The semiconductor component as claimed in claim 1, in which the first and second group III nitride layer portions form a structure of ridges and trench fillings grown laterally between the ridges, the trench fillings and ridges having mutually adjoining side walls which in each case form the interface of the index {h,k,−(h+k),l}.

4. The semiconductor component as claimed in claim 3, in which the first group III nitride layer portions additionally display a hole concentration of over 5×10¹⁷ cm⁻³.

5. The semiconductor component as claimed in one of the preceding claims, in which the interface of the index {h,k,−(h+k),l} is an a-face or an m-face of the first or second group III nitride layer portion.

6. A method of producing a c-axis oriented group III nitride layer, with the steps of:
producing at least one first c-axis oriented group III nitride layer portion on a substrate layer, which portion extends less far laterally than the substrate layer and which has an interface of the index {h,k,−(h+k),l}, h, k, and l being integers and at least one of the indices h and k being an integer greater than or equal to 1; and
depositing at least one second c-axis oriented and p-conductive group III nitride layer portion with a hole concentration of over 5×10¹⁷ cm⁻³ on the interface of the index {h,k,−(h+k),l} of the first c-axis oriented group III nitride layer portion in a growth direction perpendicular to the interface.

7. The method as claimed in claim 6, in which production of the substrate comprises a step of depositing a c-axis oriented group III nitride layer and a step of producing trenches in the c-axis oriented group III nitride layer using a lithographic method, the trenches having side walls of the index {h,k,−(h+k),l}.

8. The method as claimed in claim 6, in which production of the substrate comprises a step of producing ridges using a lithographic method, the ridges having side walls of the index {h,k,−(h+k),l}, and in which deposition of the second group III nitride layer portion comprises selective epitaxial deposition of the p-conductive region between the ridge structures, and not on a c-face of the ridge structures.

9. The method as claimed in claim 6, in which production of the substrate comprises a step of roughening a substrate surface layer by wet or dry chemical etching.

10. The method as claimed in claim 6, in which production of the substrate comprises a step of depositing a c-axis oriented group III nitride layer and creating interfaces of the index {h,k,−(h+k),l} on the c-axis oriented group III nitride layer during growth thereof, h, k, and l being integers and at least one of the indices h and k being an integer greater than or equal to 1; and
in which deposition of the second group III nitride layer portions takes place with the assistance of epitaxial overgrowth of the interfaces created.

11. The method as claimed in claim 10, in which interfaces of the index {h,k,−(h+k),l} are produced by deposition of layers acting as antisurfactants, h, k, and l being integers and at least one of the indices h and k being an integer greater than or equal to 1.

12. The method as claimed in claim 10, in which interfaces of the index {h,k,−(h+k),l} are produced by producing highly strained layers with a lattice mismatch of >1%, h, k, and l being integers and at least one of the indices h and k being an integer greater than or equal to 1.

13. The method as claimed in claim 10, in which interfaces of the index {h,k,−(h+k),l} are produced by means of a V/III precursor ratio of less than 1000 during layer deposition of a Ga-rich group III nitride layer and/or growth rates of above 5 μm/h, h, k, and l being integers and at least one of the indices h and k being an integer greater than or equal to 1.

14. The method as claimed in any one of claims 6 to 13, in which
production of the substrate includes a step of providing a substrate with a c-axis oriented group III nitride layer and a step of structuring a c-face of the substrate to expose an m-face, and in which
the step of depositing the second group III nitride layer portion includes a step of preferentially lateral growth of the second group III nitride layer portion on the m-face.

15. The method as claimed in any one of claims 6 to 14, in which production of the substrate includes a step of etching trenches and a subsequent step of filling the trenches with the second group III nitride layer portion, regions of the trenches located next to an upper trench edge being provided with a growth-inhibiting mask.

16. The method as claimed in any one of claims 6 to 15, in which the step of producing the substrate comprises:
providing a substrate with a group III nitride layer;
a first step of etching first trenches and a subsequent first step of filling the trenches, followed by
a second step of etching complementarily staggered second trenches and a second step of filling the complementarily staggered second trenches.
